(19) United States
(12) Patent Application Publication
(10) Pub. No.: US 2025/0386651 A1
(43) Pub. Date: Dec. 18, 2025

(54) LIGHT EMITTING DEVICE AND LIGHTING DEVICE

(71) Applicant: Sanken Electric Co., Ltd., Saitama-ken (JP)

(72) Inventors: Kosaku Noda, Saitama-ken (JP); Hidefumi Tachiiri, Saitama-ken (JP); Tetsuji Matsuo, Saitama-ken (JP); Tsutomu Yokota, Saitama-ken (JP)

(73) Assignee: Sanken Electric Co., Ltd., Saitama-ken (JP)

(21) Appl. No.: 19/221,493

(22) Filed: May 28, 2025

(30) Foreign Application Priority Data
Jun. 12, 2024 (JP) 2024-095383

(51) Int. Cl. H10H 29/856; H10H 29/85

(52) U.S. Cl. CPC H10H 29/856; H10H 29/8506

(57) ABSTRACT

A light emitting device is capable of suppressing peeling of a reflective resin layer disposed around a light emitting element from a substrate, and a lighting device includes the light emitting device.

The light emitting device includes: a light emitting element mounted on a top surface of a substrate; a resin wall having an opening surrounding the light emitting element, and including an opening reduction part in which an opening dimension of the opening reduces in a normal direction of the top surface of the substrate; a reflective resin layer provided on the top surface of the substrate between the opening reduction part of the resin wall and the light emitting element; and a phosphor resin layer provided above the light emitting element.

### CROSS-REFERENCE TO RELATED APPLICATION

This application claims the priority benefits of Japanese application no. 2024-095383, filed on Jun. 12, 2024. The entirety of the above-mentioned patent application is hereby incorporated by reference herein and made a part of this specification.

### BACKGROUND

### Technical Field

The disclosure relates to a light emitting device and a lighting device.

### Description of Related Art

Conventionally, a light emitting device is known in which a light emitting element, a reflective resin, and a phosphor layer covering the light emitting element and the reflective resin are laminated and disposed inside an opening of a resin wall having the opening formed on a substrate (Patent Literature 1 (Japanese Patent Application Laid-Open No. 05-029665) and Patent Literature 2 (Japanese Patent Application Laid-Open No. 2004-055632)). A resin layer such as a reflective resin is used around the light emitting element to improve light extraction efficiency.

In light emitting devices such as those described in Patent Literature 1 and Patent Literature 2 mentioned above, a resin layer, such as a reflective resin, disposed around the light emitting element is prone to peeling from the substrate.

The disclosure provides a light emitting device capable of suppressing or reducing the peeling of the reflective resin layer disposed around the light emitting element from the substrate, and a lighting device including the same.

### SUMMARY

The disclosure provides a light emitting device including: a light emitting element mounted on a top surface of a substrate; a resin wall having an opening surrounding the light emitting element, and including an opening reduction part in which an opening dimension of the opening reduces in a normal direction of the top surface of the substrate; a reflective resin layer provided on the top surface of the substrate between the opening reduction part of the resin wall and the light emitting element; and a phosphor resin layer provided above the light emitting element.

According to such a light emitting device, because the resin wall includes the opening reduction part, an anchor effect occurs in a part of the reflective resin layer provided on the top surface of the substrate between the opening reduction part and the light emitting element, and peeling of the reflective resin layer from the substrate can be easily suppressed or reduced. Also, because the resin wall includes the opening reduction part, the creep-up of the reflective resin layer onto the resin wall becomes larger, and the light extraction efficiency due to reflection can be improved. Furthermore, compared to the structure of a conventional resin wall, the height of the resin wall can be secured while suppressing the width of the resin wall, and the phosphor concentration of the phosphor resin layer may be lowered, which can contribute to cost reduction.

In this case, the light emitting element includes a light emitting layer configured to generate light therein, and the top surface of the reflective resin layer can be higher than the top surface of the light emitting layer and lower than the top surface of the light emitting element.

In this way, light exiting from the side of the light emitting layer can be effectively reflected by the reflective resin layer, thereby improving the brightness of the light emitting device. Also, by providing a relatively thick reflective resin layer, the adhesion area with other components increases, and the effect of suppressing or reducing the peeling of the reflective resin layer is enhanced. Furthermore, because the reflective resin layer is thick, light exiting diagonally downward from the light emitting layer leaking through to the back side of the substrate can be reduced.

In this case, the light emitting element includes a light emitting layer configured to generate light therein, the top surface of the reflective resin layer contacting a side surface of the light emitting element can be higher than the top surface of the light emitting layer and lower than the top surface of the light emitting element, a concave part can be provided on the top surface of the reflective resin layer between the light emitting element and the resin wall, and a part of the phosphor resin layer can enter into the concave part.

In this way, light exiting from the side of the light emitting layer can be effectively reflected by the reflective resin layer, thereby improving the brightness of the light emitting device.

Also, by providing a relatively thick reflective resin layer, the adhesion area with other components increases, and the effect of reducing the peeling of the reflective resin layer is enhanced. Furthermore, because a part of the phosphor resin layer enters into the concave part, the effect of suppressing or reducing the peeling of the reflective resin layer is further enhanced. Also, because the reflective resin layer is thick, light exiting diagonally downward from the light emitting layer leaking through to the back side of the substrate can be reduced.

In this case, the resin wall can include an opening expansion part on the opening reduction part, in which an opening dimension of the opening expands in the normal direction of the top surface of the substrate, and the reflective resin layer can extend from the opening reduction part to the opening expansion part.

In this way, peeling of the reflective resin layer can be more effectively suppressed or reduced.

In this case, the reflective resin layer can be made of a resin that is softer than the resin wall.

In this way, peeling of the reflective resin layer can be more effectively reduced.

In this case, the cross-sectional shape of the resin wall in a cross-section perpendicular to the top surface of the substrate can be any one of approximately circular, approximately elliptical, approximately rhombic, and approximately hexagonal.

Such a resin wall can be formed more easily.

In this case, a semiconductor device not including a light emitting layer is provided on the top surface of the substrate within the opening of the resin wall, and the semiconductor device not including the light emitting layer can be embedded inside the reflective resin layer.

In this way, the reflective resin layer also serves as a sealing resin, preventing intrusion of moisture or the like from the outside and occurrence of scratches due to contact with the outside.

In this case, a lighting device including the above-described light emitting device can be provided.

Therefore, a lighting device with stable light emitting properties can be provided.

As described above, according to the light emitting device of the disclosure, peeling of the reflective resin layer from the substrate can be easily suppressed or reduced. Furthermore, the light extraction efficiency by reflection can be improved. Additionally, the height of the resin wall can be secured while suppressing the width of the resin wall, and the phosphor concentration of the phosphor resin layer can be lowered.

### BRIEF DESCRIPTION OF THE DRAWINGS

FIG. 1 is a cross-sectional view showing an example of a light emitting device according to the disclosure.

FIG. 2 is a cross-sectional view showing another example (first modified example) of the light emitting device according to the disclosure.

FIG. 3 is a cross-sectional view showing another example (second modified example) of the light emitting device according to the disclosure.

FIG. 4 is a cross-sectional view showing another example (third modified example) of the light emitting device according to the disclosure.

FIG. 5 is a top view showing an example of a lighting device according to the disclosure.

FIG. 6 is a cross-sectional view showing an example of a light emitting device according to a conventional example.

### DESCRIPTION OF THE EMBODIMENTS

Hereinafter, the disclosure will be described in detail, but the disclosure is not limited thereto.

As described above, there has been a need for a light emitting device capable of suppressing or reducing the peeling of the reflective resin layer, disposed around the light emitting element, from the substrate.

As a result of diligent study, the inventors of the disclosure found the following. With a light emitting device including: a light emitting element mounted on a top surface of a substrate; a resin wall having an opening surrounding the light emitting element, and including an opening reduction part in which an opening dimension of the opening reduces in a normal direction of the top surface of the substrate; a reflective resin layer provided on the top surface of the substrate between the opening reduction part of the resin wall and the light emitting element; and a phosphor resin layer provided above the light emitting element, peeling of the reflective resin layer can be easily suppressed or reduced. Furthermore, light extraction efficiency due to reflection can be improved, and the height of the resin wall can be secured while suppressing the width of the resin wall, and the phosphor concentration of the phosphor resin layer can be lowered. Based on the findings, the inventors completed the disclosure.

Hereinafter, description is provided with reference to the drawings.

### [Light Emitting Device]

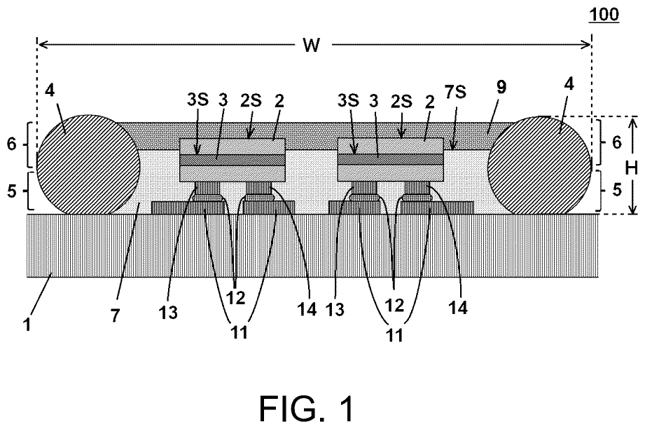

First, a light emitting device according to the disclosure will be described while referring to FIG. 1 to FIG. 3 (cross-sectional views). As shown in FIG. 1 to FIG. 3, a light emitting device 100, a light emitting device 200, and a light emitting device 300 according to the disclosure include a light emitting element 2 mounted on a substrate 1 and a resin wall 4 surrounding the light emitting element 2 and having an opening. The resin wall 4 includes an opening reduction part 5 in which the opening dimension of the opening reduces in a normal direction of a top surface of the substrate 1. A reflective resin layer 7 is provided on the top surface of the substrate 1 between the opening reduction part 5 of the resin wall 4 and the light emitting element 2. Further, a phosphor resin layer 9 is provided above the light emitting element 2.

As in the light emitting device 100, the light emitting device 200, and the light emitting device 300 of FIG. 1 to FIG. 3, the resin wall 4 includes the opening reduction part 5, and the reflective resin layer 7 enters a space between the opening reduction part 5 and the substrate 1. Due to this configuration, an anchor effect occurs in a part of the reflective resin layer 7 provided on the top surface of the substrate 1 between the opening reduction part 5 and the light emitting element 2, allowing peeling of the reflective resin layer 7 to be easily suppressed or reduced. And, this results in a light emitting device in which the reflective resin layer 7 is stably disposed on the substrate 1. Also, because the resin wall 4 includes the opening reduction part 5, the creep-up of the reflective resin layer 7 onto the resin wall 4 becomes larger, and the light extraction efficiency due to reflection can be improved. Furthermore, compared to a structure of a resin wall in which the opening dimension merely expands toward the normal direction (upward) of the top surface of the substrate 1 (e.g., as described in Patent Literature 1 and Patent Literature 2), the height of the resin wall can be increased while suppressing the width of the resin wall. Therefore, the phosphor concentration of the phosphor resin layer can be lowered, which may contribute to cost reduction.

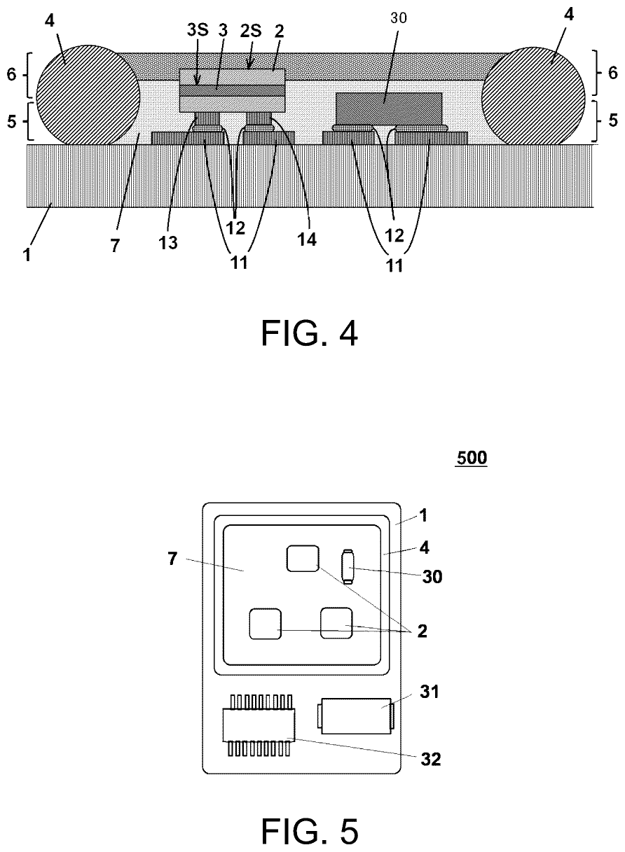

Common to the light emitting device 100, the light emitting device 200, and the light emitting device 300 of FIG. 1 to FIG. 3, as shown in FIG. 4, the light emitting device can include a semiconductor device that does not include a light emitting layer, for example, a zener diode 30, provided on the top surface of the substrate 1 within the opening of the resin wall 4, and the semiconductor device that does not include a light emitting layer can be embedded inside the reflective resin layer. Such a reflective resin layer becomes a reflective resin layer that also serves as a sealing resin, preventing intrusion of moisture or the like from the outside and occurrence of scratches due to contact with the outside.

### (Substrate)

In the light emitting device of the disclosure, the type of the substrate 1 is not particularly limited, but for example, it is preferable to use a ceramic substrate. A ceramic substrate has a small linear expansion coefficient among other practical substrates, and because the temperature properties thereof are close to the temperature properties of a resin such as a reflective resin provided on the substrate, the temperature properties of the entire light emitting device become more stable and exemplary.

### (Light Emitting Element)

In the light emitting device according to the disclosure, the type of the light emitting element 2 is not particularly limited. The light emitting element 2 can be selected and used from known LED chips and the like that output ultraviolet to blue light, and may also be an LED chip that outputs red light. An electrode 13 and an electrode 14 of the light emitting element 2 may be bonded to a metal pattern 11 provided on the substrate 1 via a bonding layer 12 such as solder.

As the light emitting element (LED chip), it is desirable to use a flip chip in which a p-type electrode and an n-type electrode are provided on one main surface side, and which emits light from the other main surface side. In the LED chip, light is output from a light emitting layer 3, but the light is output not only from above or below the LED chip but also from the side (side surface). In the case of using a flip chip, because the base part (top surface side of the light emitting element (LED chip) 2) of the LED chip becomes the light extraction surface side, it is relatively easy to secure the distance in a thickness direction from the light emitting layer 3 to the light extraction surface. As a result, even if the reflective resin layer 7 is provided up to a height above the side surface of the light emitting layer 3 and up to the top surface of the LED chip 2, the issue of the reflective resin layer 7 creeping up onto the light extraction surface becomes less likely to occur. Therefore, the light extraction efficiency of the light emitting device can be stably enhanced.

Furthermore, the number of the light emitting elements 2 disposed inside the opening of the resin wall 4 is also not particularly limited. It may be a configuration in which one light emitting element 2 is disposed in one opening. Additionally, a buffer film (not shown) that reduces total reflection of light from the side surface side of the light emitting layer 3 may be provided between the reflective resin layer 7 and the light emitting element 2. Furthermore, a material different from the reflective resin layer 7 may be provided between the reflective resin layer 7 and the resin wall 4, between the reflective resin layer 7 and the substrate 1, or/and between the reflective resin layer 7 and the phosphor resin layer 9.

### (Resin Wall)

The resin wall 4 is formed on the substrate 1 so as to surround the light emitting element 2, and forms an opening. The light emitting element 2, the reflective resin layer 7, the phosphor resin layer 9, etc. are disposed inside the opening of the resin wall 4. The resin wall 4 is sometimes also called a dam or a resin frame body. As described above, the resin wall 4 may be one that includes the opening reduction part 5. Due to the opening reduction part of the resin wall, the opening dimension of the opening decreases in the normal direction of the top surface of the substrate. The opening reduction part can also be said to have a shape that overhangs toward the opening side surrounded by the resin wall in a cross-sectional view of the resin wall.

The resin wall 4 can be made of a resin including a filler such as titanium oxide that enhances light reflection. Provided that the light emitting element 2, the reflective resin layer 7, the phosphor resin layer 9, etc. can be disposed in the opening of the resin wall 4, the shape, constituent material, etc. other than the opening reduction part 5 are not particularly limited.

As described above, it is preferable to use a ceramic substrate having high thermal conductivity as the substrate 1, but because a resist that reflects light (solder resist with light reflectivity) is not applied to the surface of the ceramic substrate, light that exits downward from the light emitting element 2 easily transmits to the back of the substrate 1. In the case of using such a ceramic substrate that easily allows light to pass to the back side (is prone to light leakage), by making the reflective resin layer thicker, light leakage to the back side of the substrate can be suppressed, and the luminous flux can be improved. To support a thick reflective resin layer, it is needed to make the resin wall relatively high as well, but as in the disclosure, by having the resin wall include the opening reduction part 5, a height (H) of the resin wall can be easily secured without widening a width (W) of the resin wall in FIG. 1, and a thick reflective resin layer can be easily and stably formed. In this way, a light emitting device capable of more effectively suppressing light leakage to the back side of the substrate 1 can be provided.

Furthermore, in the case of using a light emitting element (LED chip) of a flip-chip structure as described above, it is needed to provide the metal pattern 11 printed on the substrate 1. However, since the metal pattern 11 absorbs light, if the thick reflective resin layer 7 may be provided on the metal pattern 11, it can be expected that light absorption by the metal pattern 11 is to be reduced.

Additionally, the shape of the side opposite the opening (outer side) of the resin wall, in a cross-sectional view, is not particularly limited. The shape may be a shape asymmetrical relative to the opening side (inner side), for example, a shape perpendicular to the top surface of the substrate, or may be the same cross-sectional shape as the opening side (inner side).

Furthermore, as shown in FIG. 1 to FIG. 3, an opening expansion part 6, in which the opening dimension of the opening expands in the normal direction of the top surface of the substrate 1 in a cross-sectional view, may be included above the opening reduction part 5. In such a case, for example, it is preferable if the cross-sectional shape of the resin wall 4 is a polygonal shape such as approximately circular, approximately elliptical, approximately rhombic, approximately hexagonal, or approximately octagonal, because the resin wall can be easily formed. Here, the description “approximately” also includes slightly distorted cross-sectional shapes or partially rounded ones. The cross-sectional shape of the resin wall 4 can be adjusted by matching the shape of the nozzle used during extrusion of the resin to form the resin wall 4 to the intended cross-sectional shape of the resin wall 4. By providing the opening expansion part 6 above the opening reduction part 5, the width of the resin wall 4 can be made relatively narrow, and the height of the resin wall 4 can be made relatively high. From this, the resin wall 4 can accommodate the thick reflective resin layer 7 while relatively suppressing the size of the light emitting device.

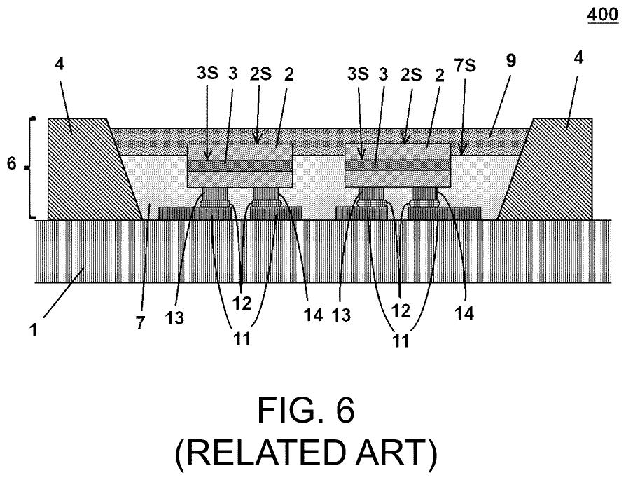

As shown in a light emitting device 400 of the conventional example in FIG. 6, in the case where the resin wall 4 is configured merely from the opening expansion part 6 in which the opening dimension of the opening expands in the normal direction of the top surface of the substrate 1 in a cross-sectional view, or in the case of a vertical wall with a constant opening dimension of the opening, the anchor effect does not act on the reflective resin layer 7, and the reflective resin layer 7 tends to easily peel from the substrate 1.

The opening shape of the resin wall 4 in a plan view of the light emitting device is not particularly limited, and examples include polygons including quadrilaterals, circles, and the like. As in the example of a lighting device 500 in FIG. 5, in the case where a quadrilateral resin wall shape is adopted in a plan view, according to use as a light source for a lamp such as a fog lamp, variations in the in-plane distribution as a surface light source can be effectively suppressed.

### (Reflective Resin Layer)

The reflective resin layer 7 is provided in the space of the opening of the resin wall 4 (the inner side surrounded by the resin wall 4) on the top surface of the substrate 1, and is also disposed around the light emitting element 2. Due to the opening reduction part 5 included in the resin wall 4, the anchor effect acts on the reflective resin layer 7, and peeling of the reflective resin layer 7 from the substrate 1 is suppressed or reduced. The reflective resin layer 7 according to the disclosure is for the purpose of reflecting light from the light emitting element 2, efficiently guiding the light upward, and improving light extraction efficiency, and is made, for example, of a resin including a filler that enhances light reflection, such as titanium oxide.

As shown in FIG. 1 to FIG. 3, it is preferable to use the light emitting element 2 having a flip-chip structure, and for the reflective resin layer 7 and the light emitting element 2 to be in contact. Furthermore, by making the thickness of the reflective resin layer 7 thicker, reducing light leakage to the back side of the substrate 1 while reflecting light upward, the upward luminance of the light emitting device can be further improved. Particularly, it is more preferable to form the reflective resin layer 7 with a thickness such that a top surface 7S of the reflective resin layer 7 is higher than the height of a top surface 3S of the light emitting layer 3 of the light emitting element 2 and lower than the height of a top surface 2S of the light emitting element 2. In this way, light exiting from the side (side surface) of the light emitting layer 3 can be reflected by the reflective resin layer 7. Therefore, the upward luminance of the light emitting device can be further improved. Also, it is desirable that the part of the reflective resin layer 7 on the light emitting element 2 side is provided to a height above the side surface of the light emitting layer 3 and up to the top surface of the LED chip 2. Furthermore, it is desirable that the part of the reflective resin layer 7 on the resin wall 4 side is provided extending from a height corresponding to at least a portion of the opening reduction part 5 on the resin wall 4 up to a height corresponding to at least a portion of the opening expansion part 6 on the resin wall 4. In this way, the anchor effect occurs, and while stably suppressing peeling of the reflective resin layer 7, light from the light emitting element 2 is reflected, the light is efficiently guided upward, and light leakage to the back side of the substrate 1 can be more effectively suppressed.

Also, like the light emitting device 100, the light emitting device 200, and the light emitting device 300 shown in FIG. 1 to FIG. 3, it is preferable that the resin wall 4 includes the aforementioned opening expansion part 6, and the reflective resin layer 7 extends from the opening reduction part 5 to the opening expansion part 6. In such a configuration, peeling of the reflective resin layer can be more effectively suppressed or reduced.

Examples of the resin constituting the reflective resin layer 7 include silicone resin and a hybrid resin having properties of both silicone resin and epoxy resin.

Furthermore, regarding a ceramic substrate, because a resist that reflects light (solder resist with light reflectivity) is not applied to the surface, light that exits downward from the light emitting element 2 easily transmits to the back of the substrate 1. Therefore, it is preferable that the reflective resin layer 7 is provided not only on the side surface of the light emitting layer of the light emitting element 2 but also on the surface side of the substrate below the side surface of the light emitting layer, making the thickness of the resin of the reflective resin layer 7 thicker, and suppressing light leakage to the back side of the substrate. In this way, while more effectively suppressing light leakage to the back side of the substrate 1, a light emitting device with good temperature properties can be provided.

Also, as described later, in the case of using a light emitting element (LED chip) of a flip-chip structure, it is needed to provide the metal pattern 11 printed on the substrate 1.

However, because the metal pattern 11 absorbs light, if the thick reflective resin layer 7 may be provided on the metal pattern 11, the reflective resin layer 7 can be expected to reduce light absorption at the metal pattern 11.

### (Phosphor Resin Layer)

The resin of the phosphor resin layer 9 according to the disclosure is not particularly limited as long as the resin is a resin including a phosphor. Examples of the resin constituting the phosphor resin layer 9 include silicone resin and a hybrid resin having properties of both silicone resin and epoxy resin. The softness of the resin of the phosphor resin layer 9 can be, for example, 15 to 35 in terms of Shore A hardness. Furthermore, the phosphor may include one or multiple types of phosphors, such as YAG phosphor.

The phosphor resin layer 9 is provided above the light emitting element 2, and it is sufficient that the phosphor resin layer 9 covers at least the output surface of the light emitting element. As shown in FIG. 1 to FIG. 3, the phosphor resin layer 9 may be formed so as to cover the entirety of the opening of the resin wall 4. Also, as shown in FIG. 1 to FIG. 3, the phosphor resin layer 9 may contact the upper part of the opening expansion part 6, or the phosphor resin layer 9 may be provided on the inner side of the opening expansion part 6.

### (Others)

An exemplary configuration of the relationship among the above-described resin wall, reflective resin layer, and phosphor resin layer will be described.

It is preferable that the resin of the phosphor resin layer 9 satisfies a predetermined relationship regarding softness with the resin of the reflective resin layer 7.

The reflective resin layer 7 can be made of a resin that is softer than the phosphor resin layer 9. Note that, in the disclosure, the softness of the resin can be defined by the Shore A hardness. In this case, the statement that the reflective resin layer 7 is a resin softer than the phosphor resin layer 9 means that the resin of the reflective resin layer 7 has lower Shore A hardness than the resin of the phosphor resin layer 9. The softness of the resin of the reflective resin layer 7, in terms of Shore A hardness, can be, for example, in the range of 17 to 26, and more preferably can be 20. Furthermore, the softness of the resin of the phosphor resin layer 9, in terms of Shore A hardness, can be, for example, 26. The base resin of the reflective resin layer 7 may be a resin of the same type as the resin constituting the phosphor resin layer 9, and may be selected from grades having different softness (Shore A hardness).

The reflective resin layer 7 covers the side surface of the light emitting element 2 to enhance the light extraction efficiency, and by using a soft resin, the influence of thermal expansion and contraction due to the heat-generating light emitting element 2 can be absorbed. Such a light emitting device is capable of suppressing changes in light emitting properties resulting from heat generation of the light emitting element.

In the case that the resin of the reflective resin layer 7 is significantly harder than the resin of the phosphor resin layer 9 (Shore A hardness: phosphor resin layer 9<<reflective resin layer 7), if the light emitting element 2 becomes a high temperature state, heat is transmitted to the reflective resin layer 7, and the reflective resin layer 7 surrounded by the resin wall 4 and the substrate 1 mainly attempts to expand toward the phosphor resin layer 9 side. In this case, if the hardness of the phosphor resin layer 9 is high, the internal stress in the reflective resin layer 7 increases. As a result, peeling may occur at the interface between the reflective resin layer 7 and the light emitting element 2, originating from locations like the corner part and the side part of the light emitting element 2, and the lowering of the light extraction efficiency of the light emitting device or a deviation of the chromaticity distribution may occur. According to the difference in Shore A hardness between the resin of the reflective resin layer 7 and the resin of the phosphor resin layer 9 being small, more preferably approximately equivalent, in the case of the reflective resin layer 7 attempting to expand toward the phosphor resin layer 9 side, the phosphor resin layer 9 can deform so as to follow the deformation of the reflective resin layer 7. As a result, the occurrence of peeling at the interface between the reflective resin layer 7 and the light emitting element 2, originating from locations like the corner part and the side part of the light emitting element 2, can be suppressed. Therefore, it is preferable that the difference in Shore A hardness between the resin of the reflective resin layer 7 and the resin of the phosphor resin layer 9 is small, more preferably approximately equivalent. It is preferable that the difference in Shore A hardness between the resin of the reflective resin layer 7 and the resin of the phosphor resin layer 9 (Shore A hardness of phosphor resin layer-Shore A hardness of reflective resin layer) is 0 or more and 20 or less, more preferably 0 or more and 18 or less.

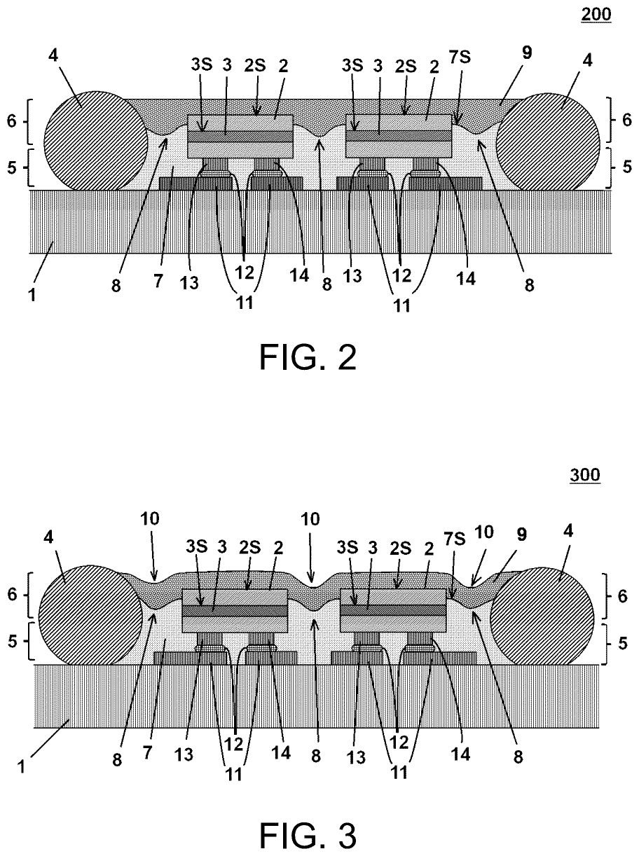

Furthermore, it is also preferable that the resin of the reflective resin layer 7 is made of a material that is more prone to curing shrinkage due to heat than the resin of the phosphor resin layer 9. In this case, the tendency for curing shrinkage can be expressed, for example, by the shrinkage rate at the time of curing, and it is preferable that the shrinkage rate of the resin of the reflective resin layer 7 is greater than the shrinkage rate of the phosphor resin layer 9. With such a combination of resins, as shown in the light emitting device 200 of a first modified example in FIG. 2 and the light emitting device 300 of a second modified example in FIG. 3, a concave part (depression) 8 is formed on the top surface of the reflective resin layer 7.

As in FIG. 2 and FIG. 3, in the case where the top surface of the reflective resin layer 7 contacting the side surface of the light emitting element 2 is formed to be higher than the top surface 3S of the light emitting layer 3 and lower than the top surface 2S of the light emitting element 2, the concave part 8 is provided on the top surface of the reflective resin layer 7 between the light emitting element 2 and the resin wall 4, and a part of the phosphor resin layer 9 enters into the concave part 8, light exiting from the side of the light emitting layer 3 can be effectively reflected by the reflective resin layer 7, thereby improving the brightness of the light emitting device. Also, by providing a relatively thick reflective resin layer 7, the adhesion area with other components increases, and the effect of reducing the peeling of the reflective resin layer 7 is enhanced. Furthermore, due to a part of the phosphor resin layer 9 entering into the concave part 8, the effect of suppressing or reducing the peeling of the reflective resin layer 7 is further enhanced. Also, because the reflective resin layer 7 is thick, light exiting diagonally downward from the light emitting layer 3 leaking through to the back side of the substrate 1 can be reduced.

Furthermore, in the case where the concave part (depression) 8 on the top surface of the reflective resin layer 7 is formed so as to be continuous with the opening expansion part 6 of the resin wall 4, the concave part (depression) 8 between the light emitting element 2 and the resin wall 4 becomes rounded, and deterioration of light emitting properties, such as light exiting from the light emitting element 2 becoming cross light and difficulty in forming a yellow ring, can be effectively suppressed, and the light emitting properties are improved. In this way, it is preferable that the reflective resin layer 7 includes the concave part (depression) 8 on the top surface. Furthermore, due to a part of the phosphor resin layer 9 entering into the concave part 8, the effect of reducing or suppressing the peeling of the reflective resin layer 7 is enhanced.

In the case where a concave part (depression) 8 is formed on the top surface of the reflective resin layer 7, as shown in the light emitting device 300 of FIG. 3, furthermore, a concave part (depression) 10 can also be formed on the surface of the phosphor resin layer 9 above the concave part of the reflective resin layer 7. Such a structure is more preferable because the angular color difference is further improved. By making the adhesion with the reflective resin layer 7 relatively high, the concave part (depression) 10 also becomes easier to form on the surface of the phosphor resin layer 9.

It is preferable that the resin wall 4 is made of a resin harder than the phosphor resin layer 9 (the resin of the phosphor resin layer 9 is softer than the resin of the resin wall 4). In this case, as the resin configuring the resin wall 4, a resin having Shore A hardness of 53 to 68 can be used. Furthermore, it is preferable that the difference in Shore A hardness between the resin of the resin wall 4 and the resin of the reflective resin layer 7 is 25 or more, more preferably 35 or more.

### (Lighting Device)

The disclosure can provide a lighting device including the above-described light emitting device. FIG. 5 shows an example of the lighting device (top view). Note that the phosphor resin layer is not illustrated so that constituent components such as the light emitting element are visible. The lighting device 500 can be provided, including: a light emitting device which includes the light emitting element 2, the zener diode 30, and the like within the opening of the resin wall 4 provided on the substrate 1; and a diode 31 and an IC 32 provided on the substrate 1 outside the opening of the resin wall 4. Specific applications of the lighting device are not particularly limited, and can be indoor lighting, outdoor lighting, headlamps for automobiles, and the like.

As described above, the light emitting device of the disclosure is a light emitting device that is capable of easily suppressing or reducing the peeling of the reflective resin layer. Furthermore, the light emitting device of the disclosure is a light emitting device that can enhance light extraction efficiency by reflection. Moreover, the phosphor concentration of the phosphor resin layer can be lowered, which may contribute to cost reduction.

The specification includes the following aspects.

[1]: A light emitting device includes: a light emitting element mounted on a top surface of a substrate;
a resin wall which has an opening surrounding the light emitting element, and includes an opening reduction part in which an opening dimension of the opening reduces in a normal direction of the top surface of the substrate;
a reflective resin layer provided on the top surface of the substrate between the opening reduction part of the resin wall and the light emitting element; and
a phosphor resin layer provided above the light emitting element.

[2]: In the light emitting device according to [1], the light emitting element includes a light emitting layer configured to generate light therein, and
a top surface of the reflective resin layer is higher than a top surface of the light emitting layer and lower than a top surface of the light emitting element.

[3]: In the light emitting device according to [1], the light emitting element includes a light emitting layer configured to generate light therein,
a top surface of the reflective resin layer contacting a side surface of the light emitting element is higher than a top surface of the light emitting layer and lower than a top surface of the light emitting element,
a concave part is provided on the top surface of the reflective resin layer between the light emitting element and the resin wall, and a part of the phosphor resin layer enters into the concave part.

[4]: In the light emitting device according to [1], [2], or [3], the resin wall includes an opening expansion part on the opening reduction part, in which an opening dimension of the opening expands in the normal direction of the top surface of the substrate, and
the reflective resin layer extends from the opening reduction part to the opening expansion part.

[5]: In the light emitting device according to [1], [2], [3], or [4], the reflective resin layer is made of a resin that is softer than the resin wall.

[6]: In the light emitting device according to [1], [2], [3], [4], or [5], a cross-sectional shape of the resin wall in a cross-section perpendicular to the top surface of the substrate is any one of approximately circular, approximately elliptical, approximately rhombic, and approximately hexagonal.

[7]: In the light emitting device according to [1], [2], [3], [4], [5], or [6],
a semiconductor device that does not include a light emitting layer is provided on the top surface of the substrate within the opening of the resin wall, and the semiconductor device that does not include the light emitting layer is embedded inside the reflective resin layer.

[8]: A lighting device includes the light emitting device according to [1], [2], [3], [4], [5], [6], or [7].

Note that the disclosure is not limited to the above-described embodiments. The above-described embodiment is illustrative, and anything that has a configuration substantially the same as the technical idea described in the claims of the disclosure and exhibits similar functions effects falls within the technical scope of the disclosure.

What is claimed is:

1. A light emitting device, comprising:
a light emitting element, mounted on a top surface of a substrate;
a resin wall, having an opening surrounding the light emitting element, and including an opening reduction part in which an opening dimension of the opening reduces in a normal direction of the top surface of the substrate;
a reflective resin layer, provided on the top surface of the substrate between the opening reduction part of the resin wall and the light emitting element; and
a phosphor resin layer, provided above the light emitting element.

2. The light emitting device according to claim 1, wherein
the light emitting element comprises a light emitting layer that generates light therein, and
a top surface of the reflective resin layer is higher than a top surface of the light emitting layer and lower than a top surface of the light emitting element.

3. The light emitting device according to claim 1, wherein
the light emitting element comprises a light emitting layer that generates light therein,
a top surface of the reflective resin layer contacting a side surface of the light emitting element is higher than a top surface of the light emitting layer and lower than a top surface of the light emitting element,
a concave part is provided on the top surface of the reflective resin layer between the light emitting element and the resin wall, and a part of the phosphor resin layer enters into the concave part.

4. The light emitting device according to claim 1, wherein
the resin wall comprises an opening expansion part on the opening reduction part, in which an opening dimension of the opening expands in the normal direction of the top surface of the substrate, and
the reflective resin layer extends from the opening reduction part to the opening expansion part.

5. The light emitting device according to claim 1, wherein the reflective resin layer is made of a resin that is softer than the resin wall.

6. The light emitting device according to claim 1, wherein a cross-sectional shape of the resin wall in a cross-section perpendicular to the top surface of the substrate is any one of approximately circular, approximately elliptical, approximately rhombic, and approximately hexagonal.

7. The light emitting device according to claim 1, wherein
a semiconductor device not comprising a light emitting layer is provided on the top surface of the substrate within the opening of the resin wall, and
the semiconductor device not comprising the light emitting layer is embedded inside the reflective resin layer.

8. A lighting device, comprising the light emitting device according to claim 1.
